(19) United States
(12) Patent Application Publication
(10) Pub. No.: US 2020/0401238 A1
(43) Pub. Date: Dec. 24, 2020

(54) A PRINTING FORM PRECURSOR AND PRINTING FORM HAVING A TWO-DIMENSIONAL CODE FOR TRACKING AND A SYSTEM FOR USING THE SAME

(71) Applicant: E. I. DU PONT DE NEMOURS AND COMPANY, Wilmington, DE (US)

(72) Inventor: Bradley K. Taylor, West Chester, PA (US)

(21) Appl. No.: 16/754,008

(22) PCT Filed: Oct. 8, 2018
(86) PCT No.: PCT/US18/54836

§ 371 Date: Apr. 6, 2020

Related U.S. Application Data
(60) Provisional application No. 62/569,760, filed on Oct. 9, 2017.

(51) Int. Cl. G06F 3/03; G03F 7/033; G06K 19/06

(52) U.S. Cl. CPC G06F 3/0321; G06K 19/06037; G03F 7/033

(57) ABSTRACT

The present invention relates to a photosensitive printing form precursor and a printing form. The printing form precursor and printing from includes a support that contains a continuous distributed two-dimensional position code. The two-dimensional position code is used for tracking the printing form precursor and the printing form.

This application claims priority under 35 U.S.C. § 119 from U.S. Provisional Application Ser. No. 62/569,760, filed Oct. 9, 2017.

### BACKGROUND OF THE INVENTION

### 1. Field of the Disclosure

This invention pertains to a printing form precursor, a system for tracking the printing form precursor, a printing form, and a system for tracking the printing form. The printing form precursor and printing form include a continuous distributed two-dimensional position code for tracking.

### 2. Description of Related Art

Flexographic printing plates are widely used for printing of packaging materials ranging from corrugated carton boxes to card boxes and to continuous webs of plastic films. Flexographic printing plates can be prepared from photopolymerizable compositions, such as those described in U.S. Pat. Nos. 4,323,637 and 4,427,759. The photopolymerizable compositions generally comprise an elastomeric binder, at least one monomer and a photoinitiator. Photosensitive elements generally have a layer of the photopolymerizable composition interposed between a support and a coversheet or a multilayer cover element.

Photopolymerizable elements for flexographic printing are characterized by their ability to crosslink or cure upon exposure to actinic radiation. Photopolymerizable elements undergo a multi-step process and typically involve at least three separate exposures to actinic radiation, to be converted into useful printing forms. In most instances, the actinic radiation is ultraviolet radiation (UV) or visible light. The photosensitive element is uniformly exposed through the backside of the plate to actinic radiation to create a floor or layer of cured photopolymer adjacent the support. Next, an imagewise exposure by actinic radiation of the front-side of the element is made through image-bearing artwork or a template, such as a photographic negative or transparency (e.g. silver halide film) or through an in-situ mask having radiation opaque areas that had been previously formed above the photopolymerizable layer. The actinic radiation enters the photopolymerizable layer through the clear areas of the transparency or mask and is blocked from entering the black or opaque areas. The exposed material crosslinks and becomes insoluble to solvents used during relief image development. The unexposed photopolymerizable areas under the opaque regions of the transparency or mask are not cross-linked and remain soluble, and are then washed away with a suitable solution, i.e., solvent or aqueous-based, leaving a relief image suitable for printing. Alternatively, a “dry” thermal development process may be used to form the relief image in which the imagewise exposed photosensitive layer is contacted with an absorbent material at a temperature sufficient to cause the composition in the unexposed portions of the photopolymerizable layer to soften or melt and flow into the absorbent material. See U.S. Pat. No. 3,264,103 (Cohen et al.); U.S. Pat. No. 5,015,556 (Martens); U.S. Pat. No. 5,175,072 (Martens); U.S. Pat. No. 5,215,859 (Martens); and U.S. Pat. No. 5,279,697 (Peterson et al.). The exposed portions of the photopolymerizable layer remain hard, that is, do not soften or melt, at the softening temperature for the unexposed portions. The absorbent material collects the softened un-irradiated material and then is separated and/or removed from the photopolymer layer. The cycle of heating and contacting the photopolymer layer may be repeated several times in order to sufficiently remove the un-irradiated areas and form a relief structure suitable for printing. The printing plate can be further treated to remove surface tackiness. After all desired processing steps, the plate is mounted on a cylinder and used for printing.

A problem exists in that printing form precursors and printing forms are difficult to track because of the lack of unique identifiable markings on each printing form precursor or printing form. Users of printing form precursors and printing forms often have numerous printing form precursors and printing forms at various stages of printing form production or the printing operation, and want to have an effective means of tracking these printing form precursors and printing forms. Manufacturers of printing form precursors have put dyes into their products to make them certain colors, and inserted markings that are machine readable or visible to human eyes to aid the identification of their printing form precursors. Manufacturers would like to track where printing form precursors are in their manufacturing process, and to record basic information such as type, gage, size, batch, etc. Any identification should survive the multi-step process to convert the photopolymerizable element to a printing form. In addition, the presence of an identifier on the photopolymerizable element should not influence the properties of the photopolymerizable element or the creation of the print surface, e.g., relief surface, on the resulting printing form, by the multi-step conversion process to the extent that print characteristics and/or functionality of the printing form are detrimentally impacted. Without a simple way to uniquely identify each printing form precursor or printing form, customers, e.g., printers, converters, trade shops, often resort to manually marking or scribing on a printing form precursor or a printing form, adding identification information to the raised relief image on the printing form, or affixing labels to plate floors. Furthermore, in some end-use applications, some printing form precursors sold in a large size by a manufacturer are cut into smaller sizes by customers for customized print jobs and for more efficient use of materials. Preprinted markings or prefixed labels on a printing form precursor may no longer uniquely identify the smaller precursors or final printing forms after cutting.

Thus, it is desirable to be able to uniquely identify and track each printing form precursor and the resulting printing form throughout their life cycles. The identifiers or markings embedded in a plate should be sophisticated enough to allow the unique identification of each plate and should survive the multi-step process for conversion from the printing form precursor to a printing form, and retain the identifiers or markings in the resulting printing form.

### SUMMARY

An embodiment provides a printing form precursor comprising a support; and a layer of a photopolymerizable material comprising a binder, a monomer, and a photoinitiator, that is adjacent the support and is sensitive to actinic radiation; wherein the support comprises a continuous distributed two-dimensional position code which codes a plurality of coordinates on the support.

Another embodiment provides that the two-dimensional position code forms a virtual raster of a code pattern consisting of a plurality of marks with associate coordinates, each mark being located at a nominal position but displaced from the nominal position in one of a plurality of directions, depending upon the value of the mark.

Another embodiment provides that the nominal positions define raster points of the virtual raster, and the raster points are situated on raster lines which intersect at a first angle.

Another embodiment provides that the raster points form an essentially orthogonal square grid.

Another embodiment provides that each mark is displaced along a raster line by a distance corresponding to between ⅛ and ¼, preferably ⅙, of the distance between two raster points.

Another embodiment provides that the mark's coordinates are determined as the center of gravity of the whole mark.

Another embodiment provides that the two-dimensional position code is arranged in a position-coding pattern to code a plurality of positions on the support, each position being coded by a specific part of the position-coding pattern and each such specific part of the position-coding pattern also contributing to the coding of adjoining positions, said position-coding pattern being based on a first string of symbols including a first predetermined number of symbols and which has the characteristic that if a group of symbols comprising a specific number of symbols less than said first number is taken from the first string of symbols, the location of said group of symbols in the first string of symbols is unambiguously defined, wherein said position-coding pattern comprises a first row of symbols comprising said first string of symbols repeated several times, and at least a second row of symbols comprising a second string of symbols repeated several times and having said characteristics of said first string of symbols.

Another embodiment provides that the second string of symbols include a second predetermined number of symbols which is different from said first number of symbols of said first string of symbols in order to obtain a displacement between the first and the second string of symbols along the first and the second row when the first and the second string of symbols are repeated.

Another embodiment provides that the second string of symbols is a subset of the first string of symbols.

Another embodiment provides that the position-coding pattern comprises a plurality of first rows and a plurality of second rows, a start position of each row being predefined to define a position in a second dimension.

Another embodiment provides that the position-coding pattern further is based on a third string of symbols having said characteristic of the first string of symbols, the third string of symbols being used to determine the position in a second dimension on the support.

Another embodiment provides that the third string of symbols is a number series consisting of numbers, each of which represents a position in a second dimension on the support.

Another embodiment provides that the first string of symbols is a series of binary numbers and the third string of symbols is a number series with a different base.

Another embodiment provides that the first and the second rows begin in predefined positions in the first and the second strings of symbols.

Another embodiment provides that the symbols comprise a first symbol of a first type and a second symbol of a second type, said first and second symbols having the same form but different size.

Another embodiment provides a system for tracking a printing form precursor, said system comprising:
(a) a printing form precursor as described above;
(b) a sensor for reading the position code at a selected area on the support, and
(c) processor means executing software for interpreting the read code in order to identify the position which corresponds to the read position code.

Another embodiment provides a printing form comprising a support and a print surface adjacent to the support, wherein the support comprises a continuous distributed two-dimensional position code which codes a plurality of coordinates on the support.

Yet another embodiment provides a system for tracking a printing form, said system comprising:
(a) a printing form as set forth above;
(b) a sensor for reading the position code at a selected area on the support, and
(c) processor means executing software for interpreting the read code in order to identify the position which corresponds to the read position code.

### BRIEF DESCRIPTION OF THE DRAWINGS

The invention can be more fully understood from the following detailed description thereof in connection with the accompanying drawings described as follows:

FIG. 1 shows schematically an embodiment of an area which is provided with a 2-D position code pattern;

FIG. 2 shows a top to bottom view of an embodiment of a photosensitive printing precursor or printing form having a support (40), a layer of a photosensitive composition, and one embodiment of a 2-D position code pattern (10) disposed on the outer layer of the support or between the photosensitive layer (20) or the relief printing layer (30) and the support;

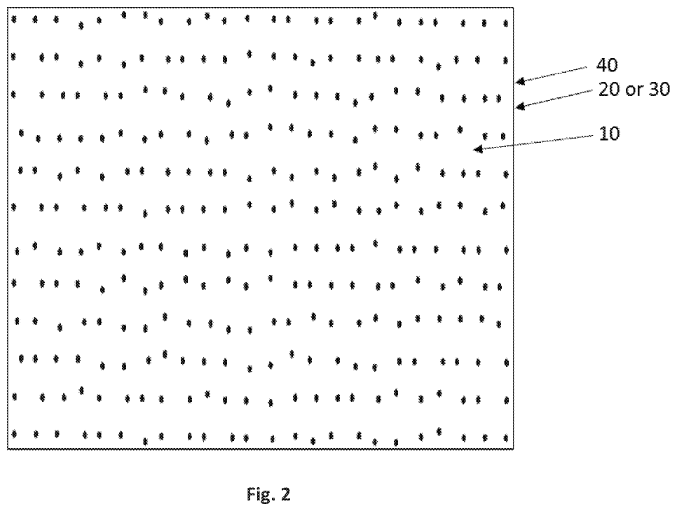

FIG. 3a shows a side view of an embodiment of a photosensitive printing precursor having a support (40), a layer of a photosensitive composition (20), and a 2-D position code marking (10) disposed on the outer layer of the support;

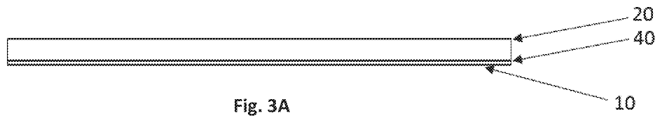

FIG. 3b shows a side view of an embodiment of a photosensitive printing precursor having a support (40), a layer of a photosensitive composition (20), and a 2-D position code marking (10) disposed between the photosensitive layer and the support;

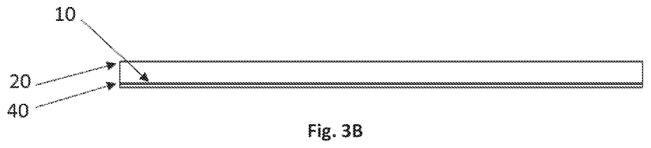

FIG. 4a shows a side view of an embodiment of a printing form having a support (40), a relief printing layer with a floor (30), and a 2-D position code marking (10) disposed on the outer layer of the support; and

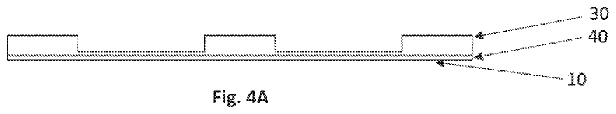

FIG. 4b shows a side view of an embodiment of a printing form having a support (40), a relief printing layer with a floor (30), and a 2-D position code marking (10) disposed between the relief printing layer and the support.

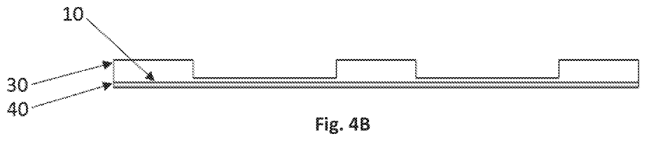

### DESCRIPTION OF THE PREFERRED EMBODIMENTS

Throughout the following detailed description, similar reference characters refer to similar elements in all figures of the drawings.

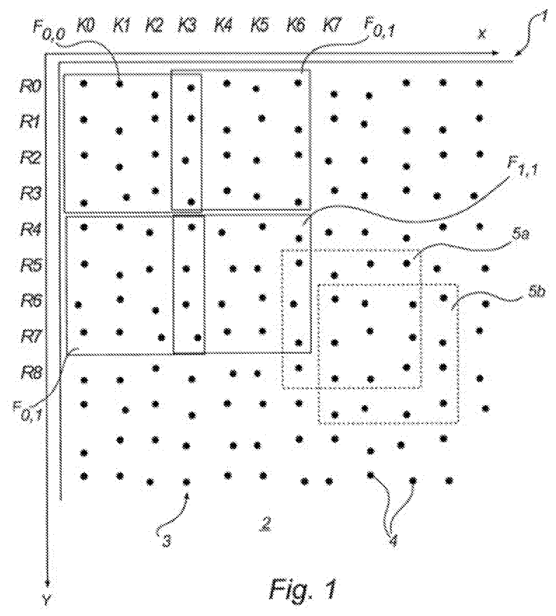

FIG. 1 shows a part of a product in the form of a plate 1, which on at least part of its surface 2 is provided with an optically readable position-coding pattern 3 which makes possible position determination.

The position-coding pattern may comprise marks 4, which are systematically arranged across the surface 2, so that it has a “patterned” appearance. The plate has an X-coordinate axis and a Y-coordinate axis. The position determination can be carried out on the whole surface of the product. The pattern can, for example, be used to provide an electronic representation of information which is written or drawn on the surface.

The position-coding pattern may comprise a virtual raster, which is neither visible to the eye nor can be detected directly by a device which is to determine positions on the surface, and a plurality of marks 4, each of which, depending upon its location, represents one of four values “1” to “4” as described below. In this connection it should be pointed out that for the sake of clarity the position-coding pattern in FIG. 1 is greatly enlarged. In addition, it is shown arranged only on part of the plate.

The position-coding pattern is so arranged that the position of a partial surface on the total writing surface is determined unambiguously by the marks on this partial surface. A first and a second partial surface 5a, 5b are shown by broken lines in FIG. 1. The second partial surface partly overlaps the first partial surface. The part of the position-coding pattern (here 4*4 marks) on the first partial surface 5a codes a first position and the part of the position-coding pattern on the second partial surface 5b codes a second position. The position-coding pattern is thus partly the same for the adjoining first and second positions. Such a position-coding pattern is called “floating” in this application. Each partial surface codes a specific position.

The present invention concerns a photosensitive element, particularly a photopolymerizable printing precursor; a system for tracking the photosensitive element to form a printing form; and a system for tracking the printing form. The photosensitive element includes a composition sensitive to actinic radiation which in most embodiments is a composition that is photopolymerizable. The photosensitive element includes a support, a layer of the photosensitive composition, and a continuous distributed two-dimensional position code. The continuous distributed two-dimensional position code is disposed on the outer surface of the support or between the support and the photosensitive layer.

The presence of the two-dimensional position code that is generated according to the present invention does not influence or only minimally influences the properties of the photosensitive element, or the creation of the print surface on the resulting printing form to an extent that print characteristics and/or functionality of the printing form are significantly impacted. It is also required that the two-dimensional position code survives the process to form the photosensitive element, and, the multi-step method to convert the photosensitive element to the printing form.

Unless otherwise stated or defined, all technical and scientific terms used herein have commonly understood meanings by one of ordinary skill in the art to which this invention pertains.

Unless otherwise indicated, the following terms as used herein have the meaning as defined below.

“Actinic radiation” refers to radiation capable of initiating reaction or reactions to change the physical or chemical characteristics of a photosensitive composition.

“Two-dimension position code” refers to machine or human (visual) detectable markings distributed two-dimensionally over a surface that encode two-dimensional (2-D) coordinates of that surface or equivalent location information of that surface.

“Halftone” is used for the reproduction of continuous-tone images, by a screening process that converts the image into dots of various sizes and typically equal spacing between centers. A halftone screen enables the creation of shaded (or grey) areas in images that are printed by transferring (or non-transferring) of a printing medium, such as ink.

“Continuous tone” refers to an image that has a virtually unlimited range of color or shades of grays, that contains unbroken gradient tones having not been screened.

“Line screen resolution”, which may sometimes be referred to as “screen ruling” is the number of lines or dots per inch on a halftone screen.

“Optical Density” or simply “Density” is the degree of darkness (light absorption or opacity) of an image, and can be determined from the following relationship:

Density=log₁₀{1/reflectance}

where reflectance is {intensity of reflected light/intensity of incident light}

“Ultraviolet Absorption” is the logarithm of the ratio of the intensities of the incident light and the transmitted light.

“Visible radiation or light” refers to a range of electromagnetic radiation that can be detected by the human eye, in which the range of wavelengths of radiation is between about 390 and about 770 nm.

“Infrared radiation or light” refers to wavelengths of radiation between about 770 and 10⁶ nm.

“Ultraviolet radiation or light” refers to wavelengths of radiation between about 10 and 390 nm.

Note that the provided ranges of wavelengths for infrared, visible, and ultraviolet are general guides and that there may be some overlap of radiation wavelengths between what is generally considered ultraviolet radiation and visible radiation, and between what is generally considered visible radiation and infrared radiation.

“White light” refers to light that contains all the wavelengths of visible light at approximately equal intensities, as in sunlight.

“Room light” refers to light that provides general illumination for a room. Room light may or may not contain all the wavelengths of visible light.

“Safelight” refers to a light with a filter, typically a colored filter, that can be used in a room without affecting the photosensitive materials. Generally the safelight illuminates so that photosensitive materials can be handled without premature exposure because the filter blocks out wavelength/s of radiation that causes reaction of the photosensitive material.

The term “photosensitive” encompasses any system in which the photosensitive composition is capable of initiating a reaction or reactions, particularly photochemical reactions, upon response to actinic radiation. Upon exposure to actinic radiation, chain propagated polymerization of a monomer and/or oligomer is induced by either a condensation mechanism or by free radical addition polymerization. While all photopolymerizable mechanisms are contemplated, the compositions and processes of this invention will be described in the context of free-radical initiated addition polymerization of monomers and/or oligomers having one or more terminal ethylenically unsaturated groups. In this context, the photoinitiator system when exposed to actinic radiation can act as a source of free radicals needed to initiate polymerization of the monomer and/or oligomer. The monomer may have non-terminal ethylenically unsaturated groups, and/or the composition may contain one or more other components, such as a binder or oligomer, that promote crosslinking. As such, the term “photopolymerizable” is intended to encompass systems that are photopolymerizable, photocrosslinkable, or both. As used herein, photopolymerization may also be referred to as curing. The photosensitive element may also be referred a photosensitive precursor, photosensitive printing precursor, printing precursor, and precursor.

Unless otherwise indicated, the terms “photosensitive element”, “printing precursor” and “printing form” encompass elements or structures in any form suitable as precursors for printing, including, but not limited to, flat sheets, plates, seamless continuous forms, cylindrical forms, plates-on-sleeves, and plates-on-carriers.

The terms “printing plate” and “printing form” are used interchangeably in this disclosure.

In addition, references in the singular may also include the plural (for example, “a” and “an” may refer to one, or one or more) unless the context specifically states otherwise.

### Photosensitive Element

The photosensitive element of the present invention is a printing form precursor used for preparing printing forms. The printing precursor includes a support, at least one layer of a photosensitive composition that is on or adjacent the support.

In most embodiments, the printing forms are relief printing forms that encompass flexographic printing forms and letterpress printing forms. The photosensitive element precursor for printing end-use and the printing form can be of any shape or form including plates and cylinders.

Relief printing is a method of printing in which the printing form prints from an image area, where the image area of the printing form is raised and the non-image area is recessed. Relief printing includes flexographic printing and letterpress printing. In some other embodiments, the printing form is suited for gravure or gravure-like printing. Gravure printing is a method of printing in which the printing form prints from an image area, where the image area is depressed and consists of small recessed cups or wells to contain the ink or printing material, and the non-image area is the surface of the form. Gravure-like printing is similar to gravure printing except that a relief printing form is used wherein the image area is depressed and consists of recessed areas forming wells to carry the ink which transfer during printing.

The support can be any flexible material that is conventionally used with photosensitive elements used to prepare printing forms. In most embodiments the support is transparent to actinic radiation to accommodate “backflash” exposure through the support. Examples of suitable support materials include polymeric films such those formed by addition polymers and linear condensation polymers, transparent foams and fabrics (fiber-resin systems). Under certain end-use conditions, metals, such as aluminum, may also be used as a support, even though a metal support is not transparent to radiation. Supports of a film composed of a synthetic resin and an antihalation agent as disclosed by Swatton et al. in EP 0 504 824 B1 are also suitable for use in the present invention. The support can be planar for use in a printing form that is plate-shaped, and can be cylindrical for use in a printing form that is a cylinder, often referred to as a printing sleeve. In one embodiment, the support is a polyester film; and, particularly a polyethylene terephthalate film. In some embodiments, the support itself can include an ultraviolet absorbent material in the film composition and/or the material can included in a layer on the support. Since the presence of the absorbent material associated with the support in combination with the 2-D position code can influence the penetration of the actinic radiation that is required to alter the physical and/or chemical characteristics of the photosensitive layer, the ultraviolet absorbance of the particular support used should be taken into account when generating suitable 2-D position code for the photosensitive element. In some embodiments, the ultraviolet absorbance of a polyethylene terephthalate film support can be 0.02 to 0.75.

The support may be in sheet form or in cylindrical form, such as a sleeve. The sleeve may be formed from single layer or multiple layers of flexible material. Flexible sleeves made of polymeric films or composite materials are preferred, as they typically are sufficiently transparent to ultraviolet radiation to accommodate backflash exposure for building a floor in the cylindrical printing element. A preferred sleeve is a multiple layered sleeve as disclosed in EP 2460657 A1. The sleeve may also be made of non-transparent, actinic radiation blocking materials, such as nickel or glass epoxy. The support has a thickness that can be from 0.002 to 0.250 inch (0.0051 to 0.635 cm). The support typically has a thickness from 0.002 to 0.050 inch (0.0051 to 0.127 cm). In some embodiments, the thickness for the sheet form is 0.003 to 0.016 inch (0.0076 to 0.040 cm). In some embodiments, the sleeve has a wall thickness from 4 to 80 mils (0.010 to 0.203 cm) or more. In other embodiments, the sleeve has a wall thickness of 10 to 40 mils (0.025 to 0.10 cm).

In the present invention, the continuous 2-D position code, a 2-D array of marks, is disposed between the support and the layer of the photosensitive composition or the outer surface of the support. An embodiment of the code is the one disclosed in U.S. Pat. No. 6,548,768 by Anoto A B. In this case, the marks are dots. The dot grid uses a 0.3 mm spacing, and the dots are about 0.1 mm in diameter. A pen camera is used to track a 6×6 array of dots (1.8×1.8 m field). Anoto A B's coding system provides a uniquely decodable 2-D area of 60 million square kilometers. The dot geometry of Anoto AB can be scaled up for the instant application. For example, if the spacing/size is increased by a factor of 33, the grid uses a 10 mm spacing and the dots are about 3 mm in diameter, a code reader looking at a 6×6 array of dots would cover 60×60 mm. This size is much smaller than the smallest photopolymer plate any customer would use, so customers will always have a readable valid code area. Additional variations of the 2-D position code, which are applicable to the instant invention, are disclosed in U.S. Pat. Nos. 6,548,768 and 6,570,104, which are incorporated by reference herein, as if fully set forth.

The continuous 2-D position code is designed to encode 2-D position continuously within the physical bounds of the code, and is limited in resolution by the discrete nature of the code geometry. When the 2-D position code is recorded on a plate precursor, it typically covers the plate across its width and continuously along its length, with the latter being the direction of the web movement of the plate production line. When the 2-D position code is recorded on a printing form, it typically covers the entire form or a section of the form. Covering only a section of the form with the continuous 2-D position code has the benefit of reducing processing cost.

The position code is fit to width and continuous in length of a plate precursor. Each plate has a unique code range, and the data is recorded into a database on the production line. The presence of the position code does not interfere with the important process-of-use aspects of the plate: in-line back exposure, adhesion, dimensional stability, back exposure, visual appearance, plate making, mounting, printing, longevity, etc. In addition, the code must be readable on raw plates through the support with a digital black layer on the other side. Thus the code is readable in reflection with a dark background. The code is readable on processed plates, preferable both facing the support (back side) or through the polymer floor (front side). In addition, the processed floor quality (solvent or thermal) must not impede code reading.

The position code can be introduced onto a plate by laser marking of the polyester support. The markings thus produced can be read by a complementary optical reading system that enables recording/detection of this marking system. The markings will likely have a visible contrast difference. Alternatively, an inkjet printer can be used to mark the dot pattern. One of ordinary skill in the art can select an ink with the proper color/dye/pigment to work with the wavelength of the reader illumination to successfully read the pattern. The markings thus introduced should not absorb or substantially absorb actinic radiation. The markings are transparent or substantially transparent to actinic radiation such that a floor of sufficient thickness for its intended purpose as a printing form can be formed upon exposure with actinic radiation through the support. Using a narrowband (narrow wavelength band) approach will help minimize any interference with in-line back exposure or plate process-of-use. One skilled in the art can also use other marking methods that enable automatic recording/detection of the marks.

The plate can be marked with the position code in advance; i.e., large rolls of support can be pre-marked with the pattern. Alternatively, the support can be marked during the unwind of the manufacturing line. Given the large range of available unique codes, and increased further by any geometrical scale-up factor, there would be sufficient unique codes to pre-mark all support rolls. The support can also be marked after plate making, i.e., after a printing form precursor has been converted to a printing form.

Each plate that is packed into a box for sale or other use must be read, so as to store the code information in a database. This can be done by reading the code on either side of the chop of each plate on the production line. All the information needed to build the internal database is available at this moment: position code that is on the plate, box the plate is packed into, plate material, gage, size, lot, date, etc. When the post-trim width of the production line, and the coding selection and scheme are known, reading the position code at each opposite side of the rectangular plate, where it has been cut to length, is sufficient to identify the entire set of 2-D position codes (the code span) on that plate.

### System for Tracking Printing Form Precursor and Printing Form

A system for customers to track a printing form precursor or printing form includes four components: 1) marked/coded plates, 2) a code reader, 3) database, and 4) software or processing means. A customer will use a reader at each stage of the print facility (or plate production) when a need to track a plate arises. For a printing form, it is common to want to track through various stages of a printing facility, e.g., storage, mounting, press area, on press, cleaning, demounting, etc. For a printing form precursor in plate production, it is common to want to track through various stages of the print form production process, e.g., imaging, back exposure, main exposure, processing, post-exposure, light finishing, etc. If the customer wants to access raw (original production) plate information, e.g. type, size, thickness, date, etc., they can access the plate manufacturer's database. The customer can use software linked to the code reader for accessing the manufacturer's database. The customer can also use the code reader and incorporate the position code information into its existing inventory control or plate tracking systems without using the manufacturer's database. In the latter case, the position code on each printing form precursor or printing form would need to be initially read at two diagonally opposite corners of the rectangular form shape. This operation defines the 2-D spatial and corresponding code span of the form, and only needs to be done once. This information becomes part of the user's local internal database built by the software. Subsequent identification only requires reading at any single arbitrary location of the form.

Typically, customers make smaller plates for use out of larger raw plates that a manufacturer supplies. For example, a customer might put four individual printing plates onto a raw 50×80 inch plate. After the plate is processed, the customer cuts the four individual plates out of the larger 50×80 inch plate and marks each individual plate. A key aspect of the instant coding system is that even after a larger raw plate is cut and turned into a number of smaller plates, the 2-D position code information stored in the database will enable unique identification and linking of the smaller cut plates back to its original raw plate. After a plate has been cut, the position code on each printing form precursor or printing form would need to be initially read at two diagonally opposite corners of the post-cut individual rectangular form shape. This operation defines the 2-D spatial and corresponding code span of the form and only needs to happen once.

The tracking system uses automatic code reading devices that utilize the optical reflection, transmission, polarization or other differences imparted by the code marking. The code readers have a localized method to aim or direct the reading operation at a specific location on the printing form precursor or printing form. The readers can communicate with a computer system and software system via wired or wireless connection or other means. Multiple readers can be used throughout a site to provide convenient operation. Fixed-location readers, e.g., positioned to read edges of plates on mounted cylinders in specific holding areas including the printing press, can also be used.

A computer based software system is used to communicate with the code readers, manage the code reading and plate tracking task, and provide basic interfaces with external information management systems. The software needs information about the original code marking scheme in order to build the internal database of printing form precursor or printing form 2-D code spans. The software can also interact with and manage data storage and retrieval with the manufacturer's database. This system enables customers to increase press utilization by knowing plate inventory at all times, and greatly facilitates process corrections, remakes, gathering information on job history, planning, productivity analysis, and continuous improvement of their operation.

The tracking method of the present disclosure does not track a 2-D path, or multiple 2-D paths, or identify selection of and/or between multiple pre-defined 2-D areas against a larger limited global area. Instead, it reads a single arbitrary location from a much larger background that does not convey any specific information in a sequence or collection, and uses this information for tracking.

The tracking method of the present disclosure does not use all the information available at each code location, namely the 2-D coordinates. Instead, it removes the specific information value of each 2-D coordinate on any precursor or printing form, and projects all possible 2-D coordinates to one piece of information, specifically the unique identification of that printing precursor or printing form.

Conventional marking and coding of each form with a unique code, perhaps distributed and/or repeated across the entire form, requires that the mark or code be applied to the precursor form after it is cut to the final rectangular size and is ready to be boxed or packaged. This requirement greatly limits the ways the mark or code can be applied to the bottom of support only, and also imposes a significant time constraint. This complicates the overall process since cutting and packing are the last steps and must be done quickly. It also logistically imperils the continuous manufacturing operation, because any marking failures or problems can force the operation to stop. The tracking method of the instant disclosure allows the marking to be done either offline or inline at a less critical part of the manufacturing operation. The continuous and 2-D nature of the code provides the advantage over a fixed mark per form. The only requirement is that the code be read at both ends prior to packaging, which can be quickly and reliably carried out.

The photopolymerizable layer is a solid layer formed of the composition comprising a binder, at least one ethylenically unsaturated compound, and a photoinitiator. The photoinitiator has sensitivity to actinic radiation. Throughout this specification actinic light will include ultraviolet radiation and/or visible light. The solid layer of the photopolymerizable composition is treated with one or more solutions and/or heat to form a relief suitable for relief printing. As used herein, the term “solid” refers to the physical state of the layer which has a definite volume and shape and resists forces that tend to alter its volume or shape. A solid layer of the photopolymerizable composition may be polymerized (photohardened), or unpolymerized, or both. In some embodiments, the layer of the photopolymerizable composition is elastomeric. In one embodiment, the photosensitive element includes a layer of photopolymerizable composition composed at least of a binder, at least one ethylenically unsaturated compound, and a photoinitiator. In another embodiment, the layer of the photopolymerizable composition includes an elastomeric binder, at least one ethylenically unsaturated compound, and a photoinitiator. In some embodiments, the relief printing form is an elastomeric printing form (i.e., the photopolymerizable layer is an elastomeric layer).

The binder can be a single polymer or mixture of polymers. In some embodiments, the binder is an elastomeric binder. In other embodiments, the layer of the photopolymerizable composition is elastomeric. Binders include natural or synthetic polymers of conjugated diolefin hydrocarbons, including polyisoprene, 1,2-polybutadiene, 1,4-polybutadiene, butadiene/acrylonitrile, and diene/styrene thermoplastic-elastomeric block copolymers. Preferably, the elastomeric block copolymer of an A-B-A type block copolymer, where A represents a non-elastomeric block, preferably a vinyl polymer and most preferably polystyrene, and B represents an elastomeric block, preferably polybutadiene or polyisoprene. In some embodiments, the elastomeric A-B-A block copolymer binders can be poly(styrene/isoprene/styrene) block copolymers, poly(styrene/butadiene/styrene) block copolymers, and combinations thereof. The binder is present in an amount of about 10% to 90% by weight of the photosensitive composition. In some embodiments, the binder is present at about 40% to 85% by weight of the photosensitive composition.

Other suitable binders include acrylics; polyvinyl alcohol; polyvinyl cinnamate; polyamides; epoxies; polyimides; styrenic block copolymers; nitrile rubbers; nitrile elastomers; non-crosslinked polybutadiene; non-crosslinked polyisoprene; polyisobutylene and other butyl elastomers; polyalkyleneoxides; polyphosphazenes; elastomeric polymers and copolymers of acrylates and methacrylate; elastomeric polyurethanes and polyesters; elastomeric polymers and copolymers of olefins such as ethylene-propylene copolymers and non-crosslinked EPDM; elastomeric copolymers of vinyl acetate and its partially hydrogenated derivatives.

The photopolymerizable composition contains at least one compound capable of addition polymerization that is compatible with the binder to the extent that a clear, non-cloudy photosensitive layer is produced. The at least one compound capable of addition polymerization may also be referred to as a monomer and can be a single monomer or mixture of monomers. Monomers that can be used in the photopolymerizable composition are well known in the art and include, but are not limited to, addition-polymerization ethylenically unsaturated compounds with at least one terminal ethylenic group. Monomers can be appropriately selected by one skilled in the art to provide elastomeric property to the photopolymerizable composition. The at least one compound capable of addition polymerization (i.e., monomer) is present in at least an amount of 5%, typically 10 to 20%, by weight of the photopolymerizable composition.

The photoinitiator can be any single compound or combination of compounds which is sensitive to actinic radiation, generating free radicals which initiate the polymerization of the monomer or monomers without excessive termination. Any of the known classes of photoinitiators, particularly free radical photoinitiators may be used. Alternatively, the photoinitiator may be a mixture of compounds in which one of the compounds provides the free radicals when caused to do so by a sensitizer activated by radiation. In most embodiments, the photoinitiator for the main exposure (as well as post-exposure and backflash) is sensitive to visible or ultraviolet radiation, between 310 to 400 nm, and preferably 345 to 365 nm. Photoinitiators are generally present in amounts from 0.001% to 10.0% based on the weight of the photopolymerizable composition.

The photopolymerizable composition can contain other additives depending on the final properties desired. Additional additives to the photopolymerizable composition include sensitizers, plasticizers, rheology modifiers, thermal polymerization inhibitors, colorants, processing aids, antioxidants, antiozonants, dyes, and fillers.

The thickness of the photopolymerizable layer can vary over a wide range depending upon the type of printing plate desired, for example, from about 0.005 inches to about 0.250 inches or greater (about 0.013 cm to about 0.64 cm or greater). In some embodiments, the photopolymerizable layer has a thickness from about 0.005 inch to 0.0450 inch (0.013 cm to 0.114 cm). In some other embodiments, the photopolymerization layer has a thickness from about 0.020 inches to about 0.112 inches (about 0.05 cm to about 0.28 cm). In other embodiments, the photopolymerizable layer has a thickness from about 0.112 inches to about 0.250 inches or greater (0.28 cm to about 0.64 cm or greater). As is conventional in the art, manufacturers typically identify the printing precursors relative to the total thickness of the printing form on press, which includes the thickness of the support and the photopolymerizable layer. The thickness of the photopolymerizable layer for the printing form is typically less than the manufacturer's designated thickness since the thickness of the support is not included.

It is well within the skill of the practitioner in the art to prepare a photosensitive precursor that includes a layer of the photopolymerizable composition formed by admixing the binder, monomer, initiator, and other ingredients.

In most embodiments, the photopolymerizable mixture is formed into a hot melt, extruded, calendered at temperatures above room temperature to the desired thickness between two sheets, such as the support and a temporary coversheet, or between one flat sheet and a release roll. Alternately, the material can be extruded and/or calendered onto a temporary support and later laminated to the desired final support. The element can also be prepared by compounding the components in a suitable mixing device and then pressing the material into the desired shape in a suitable mold. The material is generally pressed between the support and the coversheet. The molding step can involve pressure and/or heat. The coversheet may include one or more of the additional layers which transfer to the photopolymerizable layer when the photosensitive element is formed. Cylindrically shaped photopolymerizable elements may be prepared by any suitable method. In one embodiment, the cylindrically shaped elements can be formed from a photopolymerizable printing plate that is wrapped on a carrier or cylindrical support, i.e., sleeve, and the ends of the plate mated to form the cylinder shape. The cylindrically shaped photopolymerizable element can also be prepared according to the method and apparatus disclosed by Cushner et al. in U.S. Pat. No. 5,798,019. The photosensitive element includes at least one photopolymerizable layer that can be of a bi- or multi-layer construction. Further, the photosensitive element may include an elastomeric capping layer on the at least one photopolymerizable layer. Multilayer cover elements and compositions suitable as the elastomeric capping layer are disclosed in Gruetzmacher et al., U.S. Pat. Nos. 4,427,759 and 4,460,675.

The photosensitive element can include one or more additional layers on or adjacent the photosensitive layer. In most embodiments the one or more additional layers are on a side of the photosensitive layer opposite the support. Examples of additional layers include, but are not limited to, a protective layer, a capping layer, an elastomeric layer, a barrier layer, an actinic radiation opaque layer/s, and combinations thereof. The one or more additional layers can be removable, in whole or in part, during one of the steps to convert the element into a printing form, such as treating. One or more of the additional layers may cover or only partially cover the photosensitive composition layer.

The actinic radiation opaque layer is employed in digital direct-to-plate image technology in which laser radiation, typically infrared laser radiation, is used to form a mask of the image for the photosensitive element (instead of the conventional image transparency or phototool). The actinic radiation opaque layer is substantially opaque to actinic radiation that corresponds with the sensitivity of the photopolymerizable material. Digital methods create a mask image in situ on or disposed above the photopolymerizable layer with laser radiation. Digital methods of creating the mask image require one or more steps to prepare the photosensitive element prior to imagewise exposure. Generally, digital methods of in-situ mask formation either selectively remove or transfer the radiation opaque layer, from or to a surface of the photosensitive element opposite the support. The actinic radiation opaque layer can also be sensitive to laser radiation that can selectively remove or transfer the opaque layer. In one embodiment, the actinic radiation opaque layer is sensitive to infrared laser radiation. The method by which the mask is formed with the radiation opaque layer on the photosensitive element is not limited.

The photosensitive element can include an actinic radiation opaque layer disposed above a surface of the photopolymerizable layer opposite the support, or can form an assemblage with separate carrier or element that includes the actinic radiation opaque layer. Materials constituting the actinic radiation opaque layer and structures incorporating the actinic radiation opaque layer are not particularly limited, provided that the radiation opaque layer can be imagewise exposed to form the in-situ mask on or adjacent the photopolymerizable layer of the photosensitive element. The actinic radiation opaque layer may substantially cover the surface or only cover an imageable portion of the photopolymerizable layer. The actinic radiation opaque layer is substantially opaque to actinic radiation that corresponds with the sensitivity of the photopolymerizable material. The actinic radiation opaque layer can be used with or without a barrier layer. If used with the barrier layer, the barrier layer is disposed between the photopolymerizable layer and the radiation opaque layer to minimize migration of materials between the photopolymerizable layer and the radiation opaque layer. Monomers and plasticizers can migrate over time if they are compatible with the materials in an adjacent layer, which can alter the laser radiation sensitivity of the radiation opaque layer or can cause smearing and tackifying of the radiation opaque layer after imaging. The actinic radiation opaque layer is also sensitive to laser radiation that can selectively remove or transfer the opaque layer.

In one embodiment, the actinic radiation opaque layer is sensitive to infrared laser radiation. In some embodiments, the actinic radiation opaque layer comprises a radiation-opaque material, an infrared-absorbing material, and an optional binder. Dark inorganic pigments, such as carbon black and graphite, mixtures of pigments, metals, and metal alloys generally function as both infrared-sensitive material and radiation-opaque material. The optional binder is a polymeric material which includes, but is not limited to, self-oxidizing polymers, non-self-oxidizing polymers, thermochemically decomposable polymers, polymers and copolymers of butadiene and isoprene with styrene and/or olefins, pyrolyzable polymers, amphoteric interpolymers, polyethylene wax, materials conventionally used as the release layer described above, and combinations thereof. The thickness of the actinic radiation opaque layer should be in a range to optimize both sensitivity and opacity, which is generally from about 20 Angstroms to about 50 micrometers. The actinic radiation opaque layer should have a transmission optical density of greater than 2.0 in order to effectively block actinic radiation and the polymerization of the underlying photopolymerizable layer.

The photosensitive element may include the actinic radiation opaque layer disposed above and covers or substantially covers the entire surface of the photopolymerizable layer. In this case the infrared laser radiation imagewise removes, i.e., ablates or vaporizes, the radiation opaque layer to form the in-situ mask. Suitable materials and structures for this actinic radiation opaque layer are disclosed by Fan in U.S. Pat. No. 5,262,275; Fan in U.S. Pat. No. 5,719,009; Fan in U.S. Pat. No. 6,558,876; Fan in EP 0 741 330 A1; and Van Zoeren in U.S. Pat. Nos. 5,506,086 and 5,705,310. A material capture sheet adjacent the radiation opaque layer may be present during laser exposure to capture the material as it is removed from the photosensitive element as disclosed by Van Zoeren in U.S. Pat. No. 5,705,310. Only the portions of the radiation opaque layer that were not removed from the photosensitive element will remain on the element forming the in-situ mask.

In another embodiment, the photosensitive element will not initially include the actinic radiation opaque layer. A separate element bearing the radiation opaque layer will form an assemblage with the photosensitive element such that the radiation opaque layer is adjacent the surface of the photosensitive element opposite the support, which is typically is the photopolymerizable layer. (If present, a coversheet associated with the photosensitive element typically is removed prior to forming the assemblage.) The separate element may include one or more other layers, such as ejection layers or heating layers, to aid in the digital exposure process. Hereto, the radiation opaque layer is also sensitive to infrared radiation. The assemblage is exposed imagewise with infrared laser radiation to selectively transfer or selectively alter the adhesion balance of the radiation opaque layer and form the image on or disposed above the photopolymerizable layer. Materials and structures suitable for this actinic radiation opaque layer are disclosed by Fan et al. in U.S. Pat. No. 5,607,814; and Blanchett in U.S. Pat. Nos. 5,766,819; 5,840,463; and EP 0 891 877 A. As a result of the imagewise transfer process, only the transferred portions of the radiation opaque layer will reside on the photosensitive element forming the in-situ mask.

In another embodiment, digital mask formation can be accomplished by imagewise application of the radiation opaque material in the form of inkjet inks on the photosensitive element. Imagewise application of an ink-jet ink can be directly on the photopolymerizable layer or disposed above the photopolymerizable layer on another layer of the photosensitive element. Another contemplated method that digital mask formation can be accomplished is by creating the mask image of the radiation opaque layer on a separate carrier. In some embodiments, the separate carrier includes a radiation opaque layer that is imagewise exposed to laser radiation to selectively remove the radiation opaque material and form the image. The mask image on the carrier is then transferred with application of heat and/or pressure to the surface of the photopolymerizable layer opposite the support. The photopolymerizable layer is typically tacky and will retain the transferred image. The separate carrier may then be removed from the element prior to imagewise exposure.

The photosensitive element may include an elastomeric capping layer on the at least one photopolymerizable layer. The elastomeric capping layer is typically part of a multilayer cover element that becomes part of the photosensitive printing element during calendering of the photopolymerizable layer. Multilayer cover elements and compositions suitable as the elastomeric capping layer are disclosed in Gruetzmacher et al., U.S. Pat. Nos. 4,427,759 and 4,460,675. In some embodiments, the composition of the elastomeric capping layer includes an elastomeric binder, and optionally a monomer and photoinitiator and other additives, all of which can be the same or different than those used in the bulk photopolymerizable layer. Although the elastomeric capping layer may not necessarily contain photoreactive components, the layer ultimately becomes photosensitive when in contact with the underlying bulk photopolymerizable layer. As such, upon imagewise exposure to actinic radiation, the elastomeric capping layer has cured portions in which polymerization or crosslinking have occurred and uncured portions which remain unpolymerized, i.e., uncrosslinked. Treating causes the unpolymerized portions of the elastomeric capping layer to be removed along with the photopolymerizable layer in order to form the relief surface. The elastomeric capping layer that has been exposed to actinic radiation remains on the surface of the polymerized areas of the photopolymerizable layer and becomes the actual printing surface of the printing plate.

For photosensitive elements useful as flexographic printing forms, the surface of the photopolymerizable layer may be tacky and a release layer having a substantially non-tacky surface can be applied to the surface of the photopolymerizable layer. Such release layer can protect the surface of the photopolymerizable layer from being damaged during removal of an optional temporary coversheet and can ensure that the photopolymerizable layer does not stick to the coversheet. During image exposure, the release layer can prevent the image-bearing mask from binding with the photopolymerizable layer. The release layer is insensitive to actinic radiation. The release layer is also suitable as a first embodiment of the barrier layer which is optionally interposed between the photopolymerizable layer and the actinic radiation opaque layer. The elastomeric capping layer may also function as a second embodiment of the barrier layer. Examples of suitable materials for the release layer are well known in the art, and include polyamides, polyvinyl alcohol, hydroxyalkyl cellulose, copolymers of ethylene and vinyl acetate, amphoteric interpolymers, and combinations thereof.

The photosensitive printing element may also include a temporary coversheet on top of the uppermost layer of the element, which is removed prior to preparation of the printing form. One purpose of the coversheet is to protect the uppermost layer of the photosensitive printing element during storage and handling. Examples of suitable materials for the coversheet include thin films of polystyrene, polyethylene, polypropylene, polycarbonate, fluoropolymers, polyamide or polyesters, which can be subbed with release layers. The coversheet is preferably prepared from polyester, such as Mylar® polyethylene terephthalate film.

### Printing Form

In order to make the relief printing form, the photosensitive element of the present invention is exposed to actinic radiation from suitable sources. A mercury vapor arc or a UVA fluorescent lamp can be used at a distance of about 1.5 to about 60 inches (about 3.8 to about 153 cm) from the photosensitive printing element. Exposure temperatures are preferably ambient or slightly higher, i.e., about 20° C. to about 35° C. Exposure time can vary from a few seconds to tens of minutes, depending on the intensities and wavelengths of the actinic radiation, the nature and volume of the photopolymerizable layer, the desired image resolution, and the distance from the photosensitive printing element.

For photopolymerizable precursors, the method usually includes a back exposure and a front image-wise exposure. The back exposure or “backflash” can take place before, after, or during image-wise exposure. Backflash prior to image-wise exposure is generally preferred. A backflash is an overall or blanket exposure of actinic radiation through the support of the photopolymerizable precursor, for a time that can range from a few seconds to about 30 minutes. The backflash creates a shallow layer of polymerized material, or a floor, on the support side of the photopolymerizable layer and sensitizes the photopolymerizable layers, helps highlight dot resolution and also establishes the depth of the relief surface for the printing form. The floor improves adhesion of the photopolymerizable layer to the support, and provides better mechanical integrity to the photosensitive element. The floor thickness varies with the time of exposure, exposure source, the thickness of the photopolymerizable layer, etc. In some embodiments, the backflash exposure suitable to establish the floor is conducted during manufacture of the precursor, after the precursor is structurally assembled and includes photopolymerizable layer adjacent the support with the 2-D position code. In most other embodiments, a backflash exposure of minimal time and/or energy is conducted during manufacture of the precursor to assure adhesion of the photopolymerizable layer to the support, and another backflash exposure of a time and/or energy is conducted by the user during conversion from precursor to printing form to establish the floor and depth of the relief. In some embodiments the presence of the 2-D position code between the support and the photopolymerizable layer may have some impact the transmission of actinic radiation to the photopolymerizable layer, and so it may be necessary to compensate by adjusting backflash exposure time and/energy in order to create the floor with desired height.

Imagewise exposure can be carried out by exposing the photosensitive element through an image-bearing mask, which is sometimes referred to as an analog exposure or process. The image-bearing mask, a black and white transparency or negative containing the subject matter to be printed, can be made from silver halide films or other means known in the art. The image-bearing mask is placed on top of the photosensitive element after first stripping off the temporary coversheet. Imagewise exposure can be carried out in a vacuum frame, which provides proper contact of the image-bearing mask and the top surface of the photosensitive printing element, and removes atmospheric oxygen which is known to interfere with the free-radical polymerization process.

Alternatively to the analog process, imagewise exposure can be carried out by exposing the photosensitive element through an actinic radiation opaque mask that is formed digitally usually with laser radiation and resides adjacent or on the photopolymerizable layer. The formation of the mask digitally with laser radiation may be referred to as a digital exposure or process, and the use of a digitally formed mask may be referred to as digital direct-to plate image process. Some suitable direct-to-plate image formation methods are disclosed in U.S. Pat. Nos. 5,262,275; 5,719,009; U.S. Pat. No. 5,607,814; van Zoeren, U.S. Pat. No. 5,506,086; and EP 0 741 330 A1. For the digital process, the presence of the infrared-sensitive (and/or radiation opaque) layer is required. An image-bearing mask is formed directly onto the infrared-sensitive layer in situ using an infrared laser exposure engine. Imagewise exposure of printing forms through such digitally formed mask can be done without using a vacuum frame, simplifying the method of making the printing form. In one embodiment, the exposure process involves (1) imagewise ablating the infrared-sensitive layer of the photosensitive printing element described above to form a mask; and (2) overall exposing the photosensitive element to actinic radiation through the mask. The exposure can be carried out using various types of infrared lasers, which emit in the range 750 to 20,000 nm, preferably in the range 780 to 2,000 nm. Diode lasers may be used, but Nd:YAG lasers emitting at 1060 nm are preferred. Alternative methods of forming the mask digitally, i.e., by transfer of actinic radiation opaque mask, or lamination of a digitally formed mask, as well as formation of the mask by ink-jetting are described above for the photosensitive element.

After mask formation digitally or by generating a negative film, the photosensitive element is then exposed to actinic radiation through the mask. On exposure, the transparent areas of the negative or the blank areas of the digital mask allow addition polymerization or crosslinking to take place, while the opaque areas remain uncrosslinked. Imagewise exposing the photopolymerizable element to actinic radiation creates exposed portions that polymerize, and unexposed portions that remain unpolymerized of the photopolymerizable layer. Exposure is of sufficient duration to crosslink the exposed areas down to the support or to the back exposed layer, i.e., floor. Imagewise exposure time is typically much longer than backflash time, and ranges from a few to tens of minutes. Actinic radiation sources encompass the ultraviolet and visible wavelength regions. The suitability of a particular actinic radiation source is governed by the photosensitivity of the initiator and the at least one monomer used in preparing the photosensitive element. The preferred photosensitivity of most common relief printing forms is in the UV and deep visible area of the spectrum, as they afford better room-light stability. Examples of suitable visible and UV sources include carbon arcs, mercury-vapor arcs, fluorescent lamps, electron flash units, electron beam units, lasers, and photographic flood lamps. The most suitable sources of UV radiation are the mercury vapor lamps, particularly the sun lamps. Examples of industry standard radiation sources include the Sylvania 350 Blacklight fluorescent lamp (FR48T12/350 VL/VHO/180, 115 w), and the Philips UV-A “TL”-series low-pressure mercury-vapor fluorescent lamps. These radiation sources generally emit long-wave UV radiation between 310-400 nm. Flexographic printing plates sensitive to these particular UV sources use initiators that absorb between 310-400 nm. It is contemplated that the imagewise exposure to infrared radiation for those embodiments which include the infrared-sensitive layer and the overall exposure to actinic radiation can be carried out in the same equipment.

Following overall exposure to UV radiation through the image-bearing mask, the photosensitive printing element is treated to remove unpolymerized areas in the photopolymerizable layer and thereby form a relief image. The treating step is not limited, and includes conventional steps to transform the exposed photosensitive element into the desired printing form. Treating can include treatment with one or more solutions, such as washout or by applying heat, etc. as appropriate for the particular type of photosensitive element that converts the imaged photosensitive layer to a printing form. Treatment of the photosensitive printing element can include (1) “wet” development wherein the photopolymerizable layer is contacted with a suitable developer solution to washout unpolymerized areas and (2) “dry” development wherein the photopolymerizable layer is heated to a development temperature which causes the unpolymerized areas to melt or soften and is contacted with an absorbent material to wick away the unpolymerized material. Dry development may also be called thermal development.

Wet development is usually carried out at about room temperature. The developer solution can include an organic solvent, an aqueous or a semi-aqueous solution, or water. The choice of the developer solution will depend primarily on the chemical nature of the photopolymerizable composition to be removed. A suitable organic solvent developer includes an aromatic or an aliphatic hydrocarbon, an aliphatic or an aromatic halohydrocarbon solvent, or a mixture of such solvents with a suitable alcohol. Other organic solvent developers have been disclosed in published German Application 38 28 551. A suitable semi-aqueous developer can contain water and a water miscible organic solvent and an alkaline material. A suitable aqueous developer can contain water and an alkaline material. Other suitable aqueous developer solution combinations are described in U.S. Pat. No. 3,796,602. Development time can vary, but it is preferably in the range of about 2 to about 25 minutes. The developer solution can be applied in any convenient manner, including immersion, spraying, and brush or roller application. Brushing aids can be used to remove the unpolymerized portions of the photosensitive printing element. Washout can be carried out in an automatic processing unit which uses developer and mechanical brushing action to remove the unexposed portions of the resulting relief printing form, leaving a relief constituting the exposed image and the floor.

Following treatment by developing in solution, the printing forms are generally blotted or wiped dry, and then more fully dried in a forced air or infrared oven. Drying times and temperatures may vary, however, typically the plate can be dried for about 60 minutes to about 120 minutes at about 60° C. High temperatures are not recommended because the support can shrink, and this can cause registration problems.

In thermal development, the photopolymerizable layer can be heated to a development temperature typically between about 40° C. and 200° C. which causes the unpolymerized areas to liquefy, that is, to melt, soften, or flow. The photopolymerizable layer can then be contacted with a development material to remove the unpolymerized photopolymerizable composition. The polymerized areas of the photopolymerizable layer have a higher melting temperature than the unpolymerized areas and therefore do not melt at the development temperatures (see U.S. Pat. No. 5,215,859 and WO 98/13730). Apparatus suitable for thermal development of photosensitive printing elements is disclosed in U.S. Pat. Nos. 5,279,697 and 6,797,454.

In another alternate embodiment the photosensitive element may be suitably reinforced and then imagewise exposed to laser radiation to engrave or remove the reinforced layer in depth imagewise. U.S. Pat. Nos. 5,798,202; 5,804,353; and 6,757,216 B2 disclose suitable processes for making a printing form by laser engraving a reinforced elastomeric layer on a flexible support. The processes disclosed in U.S. Pat. Nos. 5,798,202 and 5,804,353 involve reinforcing and laser engraving a single-layer, or one or more layers of a multi-layer, relief printing precursor comprised of a reinforced elastomeric layer on a flexible support. The elastomeric layer is reinforced mechanically, or thermochemically, or photochemically or combinations thereof. Mechanical reinforcement is provided by incorporating reinforcing agents, such as finely divided particulate material, into the elastomeric layer. Photochemical reinforcement is accomplished by incorporating photohardenable materials into the elastomeric layer and exposing the layer to actinic radiation. Photohardenable materials include photocrosslinkable and photopolymerizable systems having a photoinitiator or photoinitiator system.

What is claimed is:

1. A printing form precursor comprising:
a) a support; and
b) a layer of a photopolymerizable material comprising a binder, a monomer, and a photo initiator, that is adjacent the support and is sensitive to actinic radiation;
wherein the support comprises a continuous distributed two-dimensional position code which codes a plurality of coordinates on the support.

2. The printing form precursor of claim 1, wherein said two-dimensional position code forms a virtual raster of a code pattern consisting of a plurality of marks with associate coordinates, each mark being located at a nominal position but displaced from the nominal position in one of a plurality of directions, depending upon the value of the mark.

3. The printing form precursor of claim 2, wherein the nominal positions define raster points of the virtual raster, and the raster points are situated on raster lines which intersect at a first angle.

4. The printing form precursor of claim 3, wherein the raster points form an essentially orthogonal square grid.

5. The printing form precursor of claim 4, wherein each mark is displaced along a raster line by a distance corresponding to between ⅛ and ¼, preferably ⅙, of the distance between two raster points.

6. The printing form precursor of claim 5, wherein the mark's coordinates are determined as the center of gravity of the whole mark.

7. The printing form precursor of claim 1, wherein said two-dimensional position code is arranged in a position-coding pattern to code a plurality of positions on the support, each position being coded by a specific part of the position-coding pattern and each such specific part of the position-coding pattern also contributing to the coding of adjoining positions, said position-coding pattern being based on a first string of symbols including a first predetermined number of symbols and which has the characteristic that if a group of symbols comprising a specific number of symbols less than said first number is taken from the first string of symbols, the location of said group of symbols in the first string of symbols is unambiguously defined, wherein said position-coding pattern comprises a first row of symbols comprising said first string of symbols repeated several times, and at least a second row of symbols comprising a second string of symbols repeated several times and having said characteristics of said first string of symbols.

8. The printing form precursor of claim 7, wherein said second string of symbols including a second predetermined number of symbols which is different from said first number of symbols of said first string of symbols in order to obtain a displacement between the first and the second string of symbols along the first and the second row when the first and the second string of symbols are repeated.

9. The printing form precursor of claim 8, wherein said second string of symbols is a subset of the first string of symbols.

10. The printing form precursor of claim 8, wherein the position-coding pattern comprises a plurality of first rows and a plurality of second rows, a start position of each row being predefined to define a position in a second dimension.

11. A system for tracking a printing form precursor, said system comprising:
(a) a printing form precursor according to claim 1;
(b) a sensor for reading the position code at a selected area on the support, and
(c) processor means executing software for interpreting the read code in order to identify the position which corresponds to the read position code.

12. The system of claim 11, wherein said two-dimensional position code forms a virtual raster of a code pattern consisting of a plurality of marks with associate coordinates, each mark being located at a nominal position but displaced from the nominal position in one of a plurality of directions, depending upon the value of the mark.

13. The system of claim 11, wherein said two-dimensional position code is arranged in a position-coding pattern to code a plurality of positions on the support, each position being coded by a specific part of the position-coding pattern and each such specific part of the position-coding pattern also contributing to the coding of adjoining positions, said position-coding pattern being based on a first string of symbols including a first predetermined number of symbols and which has the characteristic that if a group of symbols comprising a specific number of symbols less than said first number is taken from the first string of symbols, the location of said group of symbols in the first string of symbols is unambiguously defined, wherein said position-coding pattern comprises a first row of symbols comprising said first string of symbols repeated several times, and at least a second row of symbols comprising a second string of symbols repeated several times and having said characteristics of said first string of symbols.

14. A printing form comprising a support and a print surface adjacent to the support, wherein the support comprises a continuous distributed two-dimensional position code which codes a plurality of coordinates on the support.

15. A system for tracking a printing form, said system comprising:
(a) a printing form according to claim 14;
(b) a sensor for reading the position code at a selected area on the support, and
(c) processor means executing software for interpreting the read code in order to identify the position which corresponds to the read position code.
